(19) United States
(12) Patent Application Publication
(10) Pub. No.: US 2010/0308380 A1
(43) Pub. Date: Dec. 9, 2010

(54) DUAL DAMASCENE PROCESSING FOR GATE CONDUCTOR AND ACTIVE AREA TO FIRST METAL LEVEL INTERCONNECT STRUCTURES

(75) Inventors: Mary Beth Rothwell, Yorktown Heights, NY (US); Roy R. Yu, Yorktown Heights, NY (US)

Correspondence Address: CANTOR COLBURN LLP-IBM YORKTOWN, 20 Church Street, 22nd Floor, Hartford, CT, 06103, US

(73) Assignee: INTERNATIONAL BUSINESS MACHINES CORPORATION, Armonk, NY (US)

(21) Appl. No.: 12/478,850

(22) Filed: Jun. 5, 2009

(51) Int. Cl. H01L 23/48; H01L 21/768; H01L 29/78

(52) U.S. Cl. 257/288; 438/656; 438/666; 257/E23.011; 257/E29.255; 257/E21.585

(57) ABSTRACT

A method of forming a semiconductor device includes forming a first interlevel dielectric (ILD) layer over one or more transistor structures formed on a substrate, the one or more transistor structures including an active area, source/drain contact and a gate conductor formed over the substrate; forming a first metal (M1) level trench in an upper portion of the first ILD layer, followed by forming vias in a lower portion of the first ILD layer, down to the source/drain contact and down to the gate conductor; and filling both the trench and vias with a conductive material, thereby resulting in a dual damascene metal process at and below the M1 level of the semiconductor device.

### BACKGROUND

The present invention relates generally to semiconductor device manufacturing techniques and, more particularly, to dual damascene processing for gate conductor and active device area to first metal level interconnect structures.

In the manufacture of integrated circuit (IC) devices, tungsten (W) is a preferred conductive material for forming interconnect structures or “plugs” between transistor device terminals, such as gate conductors “PC” and active device “RX” areas (source/drain regions) and a first level of metallization, M1, which first level typically comprises a copper material. However, due to the increased scaling of IC devices, the resulting decrease in the critical dimension (CD) of the plug structures results in difficulties with the fill quality of the W material, which is formed by techniques such as chemical vapor deposition (CVD). In particular, as the W fill quality starts to degrade the resulting contact resistance increases so as to adversely affect the performance of the circuitry.

For contact area (CA) via CDs below 50 nanometers (nm), there is a disproportional reduction in size for the respective aspect ratios of the CA vias (connecting to the gate conductors) and the RX vias (connecting to the source/drain regions). This is due to the fact that the CA vias are shorter in height since the gate structure rises above the semiconductor substrate while the RX via extends from all the way down from the first metal level to the semiconductor substrate level. Because of the manner in which the vias are conventionally are filled (i.e., by W deposition and subsequent chemical mechanical polishing (CMP)), the oxide overburden of the dielectric layer does not reduce as fast as the PC/RX CD, and thus the aspect ratio increases.

At the same time, conventional CA reactive ion etching (RIE) tends to produce a large top flare in order to etch to the depths needed to contact the PC/RX areas. As a result, the CA/RX aspect ratio has been extended beyond a traditional W process fill window, in turn dramatically increasing contact resistances for CA CDs below 60 nm.

### SUMMARY

In an exemplary embodiment, a method of forming a semiconductor device includes forming a first interlevel dielectric (ILD) layer over one or more transistor structures formed on a substrate, the one or more transistor structures including an active area, source/drain contact and a gate conductor formed over the substrate; forming a first metal (M1) level trench in an upper portion of the first ILD layer, followed by forming vias in a lower portion of the first ILD layer, down to the source/drain contact and down to the gate conductor; and filling both the trench and vias with a conductive material, thereby resulting in a dual damascene metal process at and below the M1 level of the semiconductor device.

In another embodiment, a method of forming a semiconductor device, the method comprising forming a first interlevel dielectric (ILD) oxide layer over a cap layer that protects one or more transistor structures formed on a substrate, the one or more transistor structures including an active area, source/drain contact and a gate conductor formed over the substrate; forming a first metal (M1) level trench in an upper portion of the first ILD layer by photoresist pattering and reactive ion etching (RIE), followed by forming vias in a lower portion of the first ILD layer, down to the source/drain contact and down to the gate conductor by photoresist pattering and reactive ion etching (RIE); and filling both the trench and vias with a conductive material, thereby resulting in a dual damascene metal process at and below the M1 level of the semiconductor device.

In another embodiment, a semiconductor device includes a substrate, one or more transistor structures formed on the substrate, including an active area, source/drain contact and a gate conductor formed over the substrate; a first interlevel dielectric (ILD) layer formed over the one or more transistor structures, the one or more transistor; and a first metal (M1) level trench formed in an upper portion of the first ILD layer, and vias formed in a lower portion of the first ILD layer, down to the source/drain contact and down to the gate conductor, wherein both the trench and vias are filled with copper.

### BRIEF DESCRIPTION OF THE SEVERAL VIEWS OF THE DRAWINGS

Referring to the exemplary drawings wherein like elements are numbered alike in the several Figures:

FIGS. 1(a) through 1(h) are a series of cross sectional views illustrating an existing process of forming single damascene (tungsten) plugs, followed by single damascene (copper) first metal level wiring; and

FIGS. 2(a) through 2(f) are a series of cross sectional views illustrating a dual damascene process of forming CA/RX plugs with first metal level wiring for semiconductor devices, in accordance with an embodiment of the invention.

### DETAILED DESCRIPTION

Disclosed herein is a dual damascene interconnect process that is implemented at the CA/RX to M1 level of semiconductor device manufacturing. In an exemplary embodiment, the M1 level trench is first formed through lithography and RIE in order to maintain the integrity of the subsequently formed PC/RX vias. The CA lithography and RIE is then performed to define vias that contact the PC and RX regions. This “line first” approach maintains a better CA CD and RIE budget due to the reduced initial CA via height, thereby simplifying the lithography process. A metal fill (e.g., copper) process then used to fill the CA/RX via and M1 trench structures, after which standard back end of line (BEOL) metal processing as known in the art may proceed.

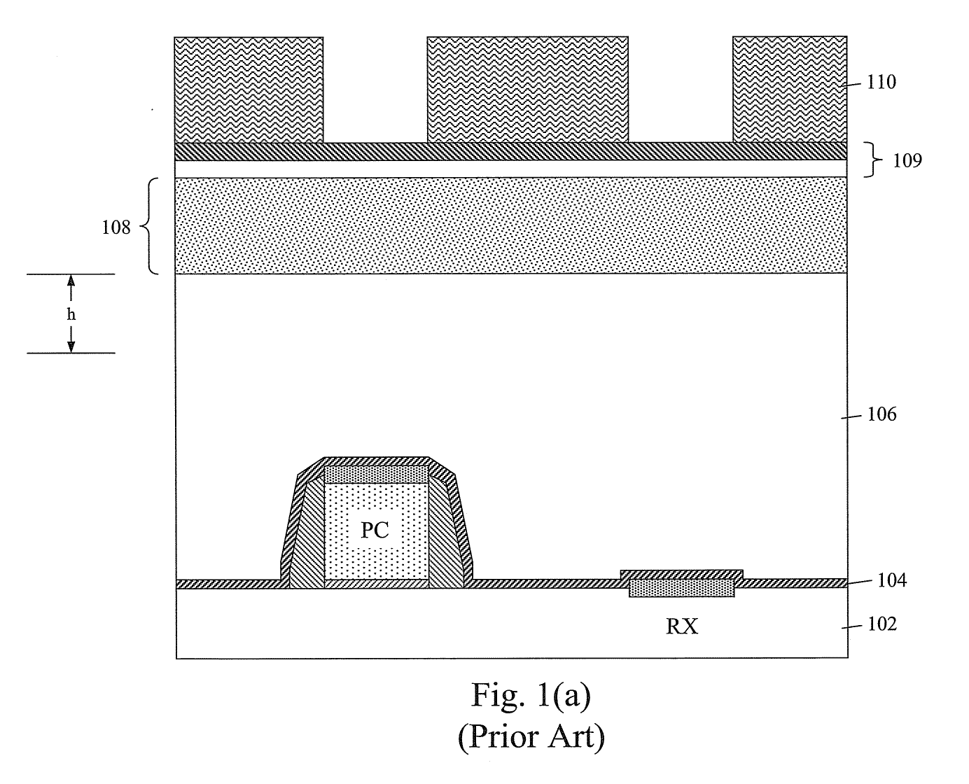

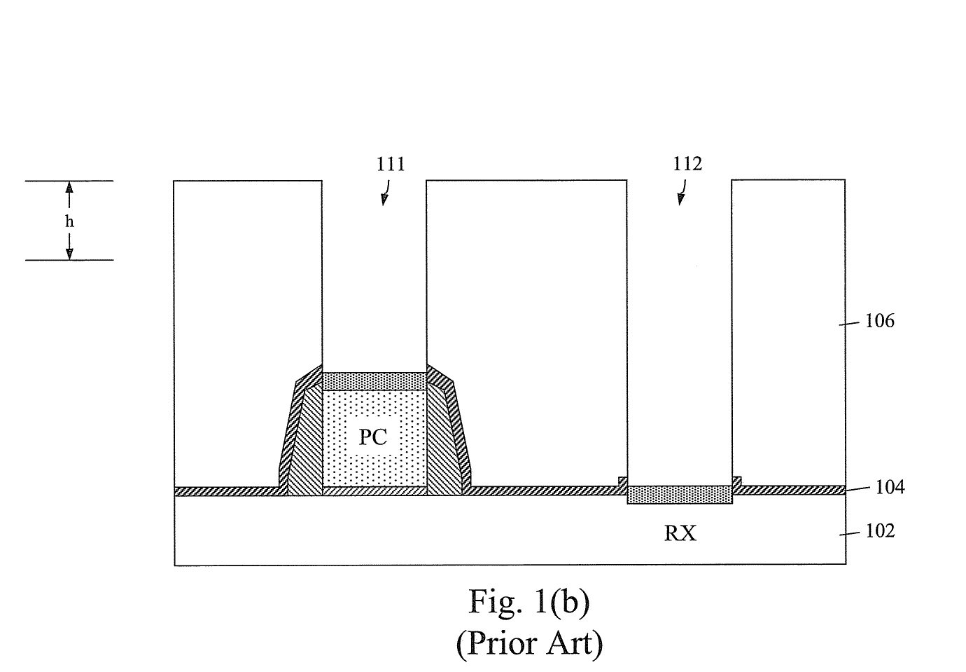

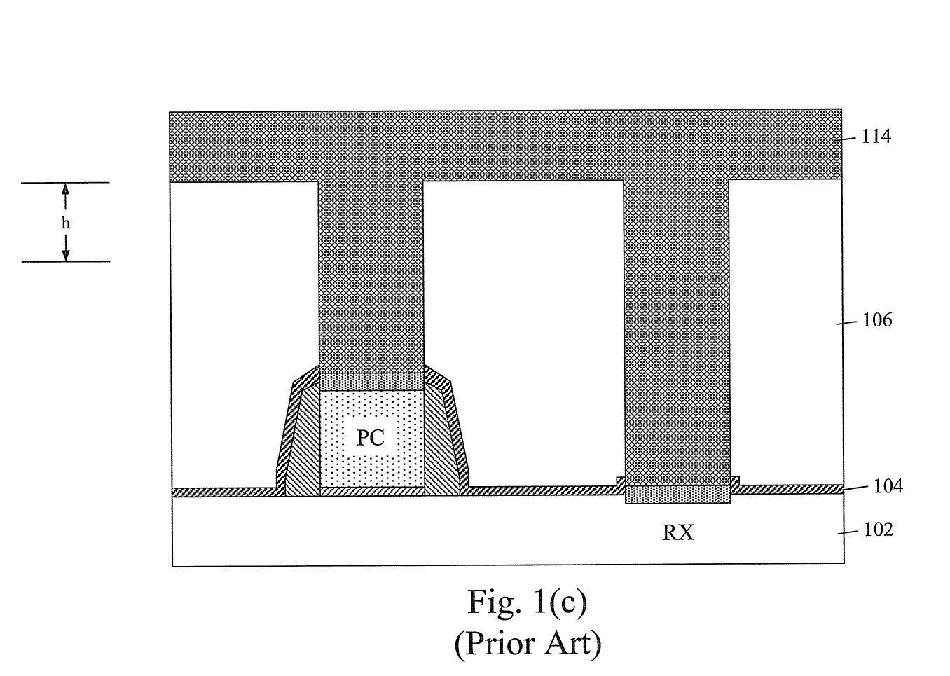

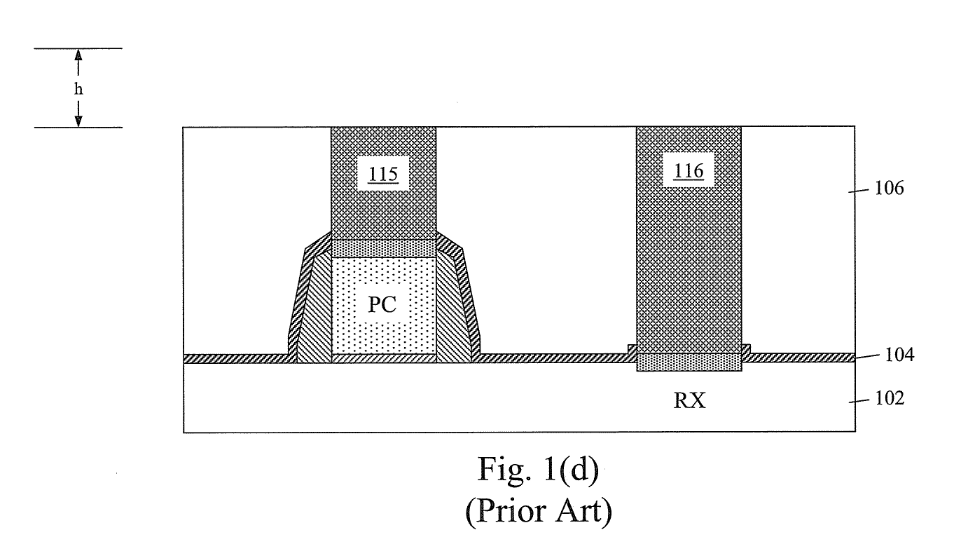

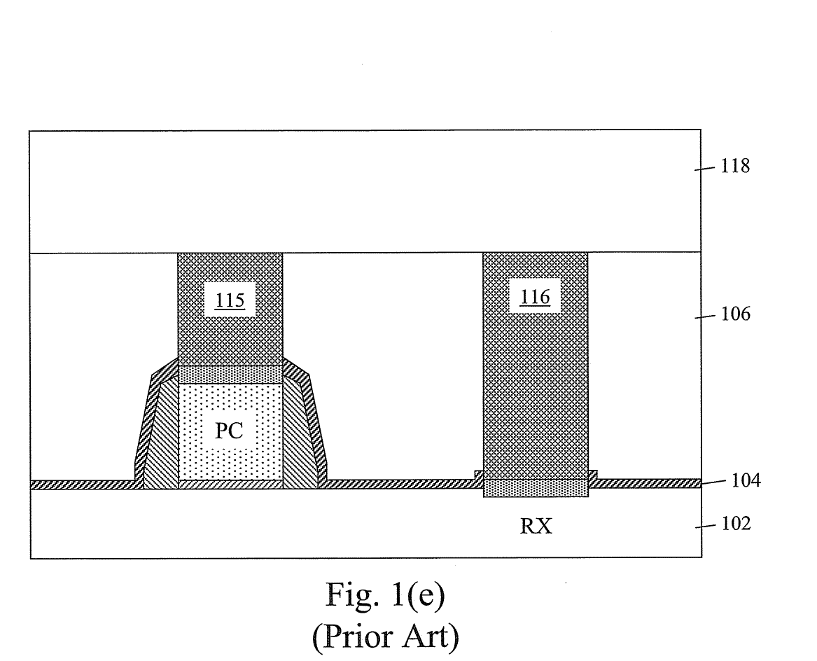

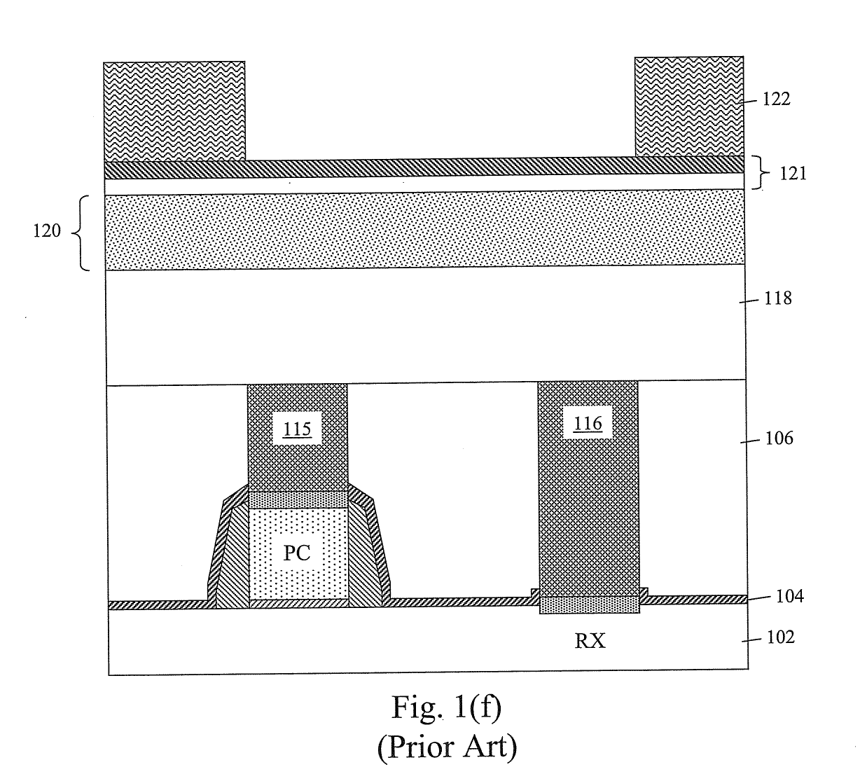

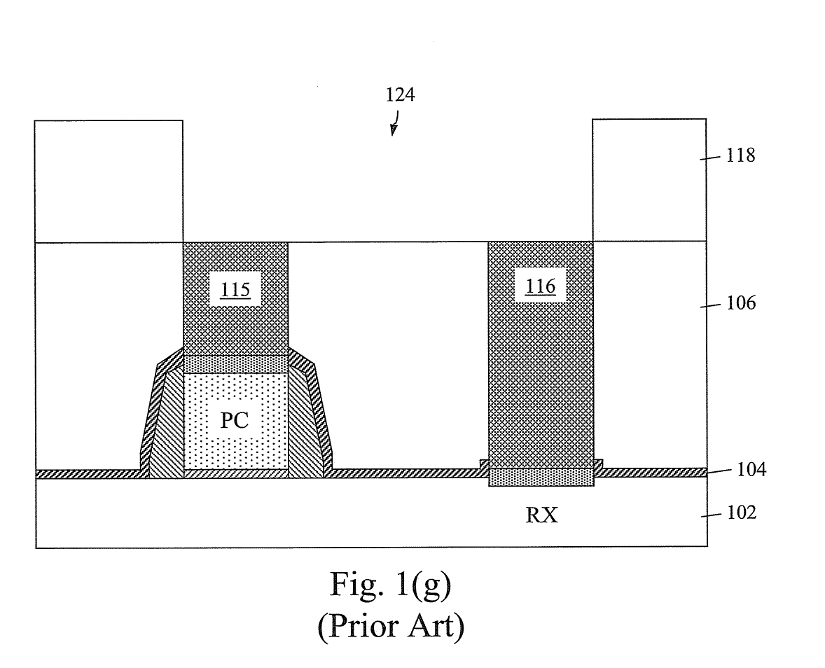

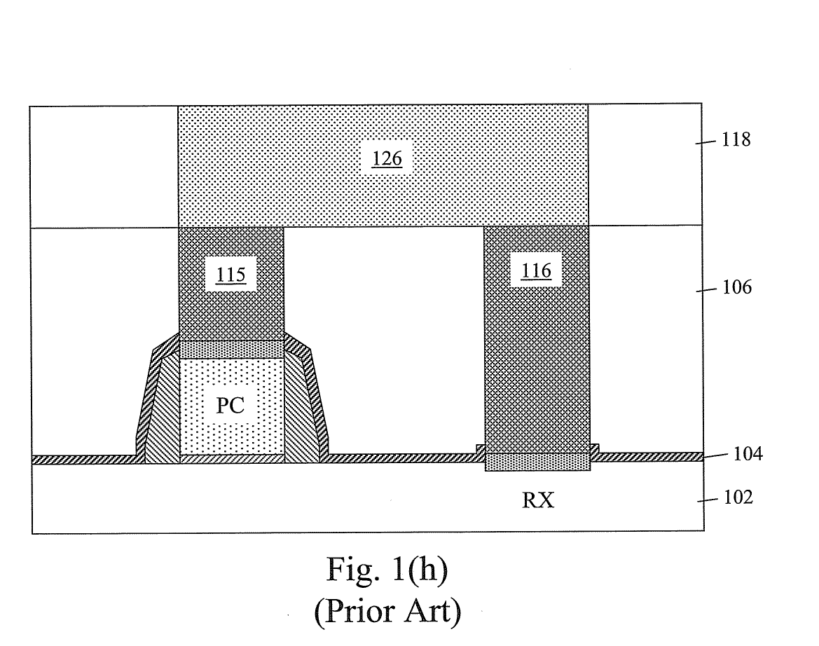

Referring initially to FIGS. 1(a) through 1(g), there is shown a sequence of cross-sectional views of a conventional process flow for single damascene CA-W fill and single damascene Cu-M1 fill in semiconductor device manufacturing. Beginning with FIG. 1(a), a semiconductor substrate 102 has a plurality of transistor device regions formed thereupon, as is known in the art. For ease of description, individual transistor structures are not specifically labeled as such in FIG. 1(a), such as source/drain terminals, gate conductors, gate dielectric layers, spacers and the like, as they are well known in the art. However, the designation “PC” denotes a gate conductor to which a PC via is subsequently connected, and “RX” denotes an active source/drain region, to which an RX via is subsequently connected. The transistor structures formed in the front end of line (FEOL) regions of the semiconductor device may be protected by a cap layer 104 (e.g., a nitride layer).

As also known in the art, an interlevel dielectric (ILD) layer 106, such as an oxide layer, is then formed over the capped transistor structures. Due to the relatively low selectivity of tungsten versus oxide during CMP, the oxide layer 106 is formed at a greater initial thickness with respect to the final intended via height of the CA and RX vias. This extra thickness is represented by the dimension “h” in FIG. 1(a). As is further illustrated, an organic tri-resist layer 108 is formed over the oxide layer 106, which is used to transfer a high aspect ratio via pattern into the oxide layer 106. An oxide containing hardmask layer 109 is formed over the tri-resist layer 108, followed by a photoresist layer 110 that is shown patterned with the CA and RX via openings.

FIG. 1(b) illustrates the transfer of the via pattern into the oxide layer 106, resulting in the formation of the CA via 111 and the taller RX via 112. Notably, the height of the oxide layer 106 is still at the increased thickness prior to deposition of the tungsten fill material 114, which is shown in FIG. 1(c). Then, in FIG. 1(d), the device is planarized by CMP so as to result in a completed PC tungsten plug or stud 115 and a completed RX tungsten plug 116. As will be noted, the CMP process removes the budgeted oxide thickness, in addition to the W overfill material.

With the middle end of line (MEOL) fabrication complete at this point, the back end of line (BEOL) processing starts in FIG. 1(f) by forming another oxide layer 118 over oxide layer 106 and the completed plugs 115, 116. The oxide layer 118 is the dielectric corresponding to the M1 metal, formed in single damascene fashion. Similar to the tungsten plug formation process, another tri-resist layer 120 and oxide containing hardmask 121 is formed over the oxide layer 118. This is followed by patterning of the M1 trenches in a photoresist layer 112, also shown in FIG. 1(f).

As shown in FIG. 1(g), the trench pattern 124 is etched into the oxide layer 118. Finally, in FIG. 1(h), the M1 level metal (e.g., copper) is deposited, and polished by CMP to form an M1 line 126 in electrical contact with vias 115 and 116. One skilled in the art will recognize that additional processing steps (e.g., liner/seed formation) are not illustrated for purposes of simplicity. Thereafter, additional BEOL processing as known in the art is performed (which may include single or dual damascene processing) to form upper metal level wiring structures.

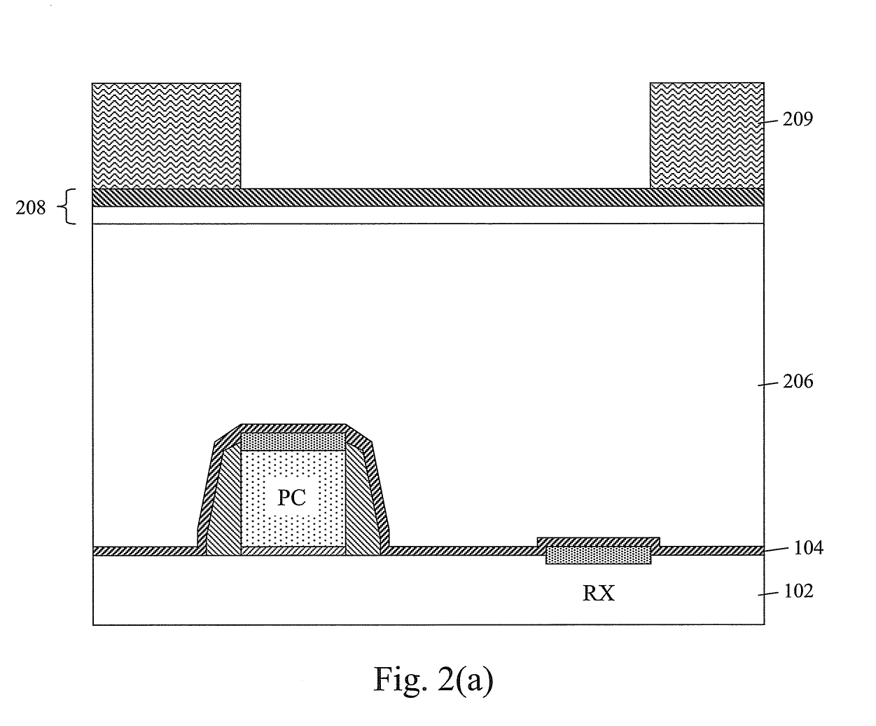

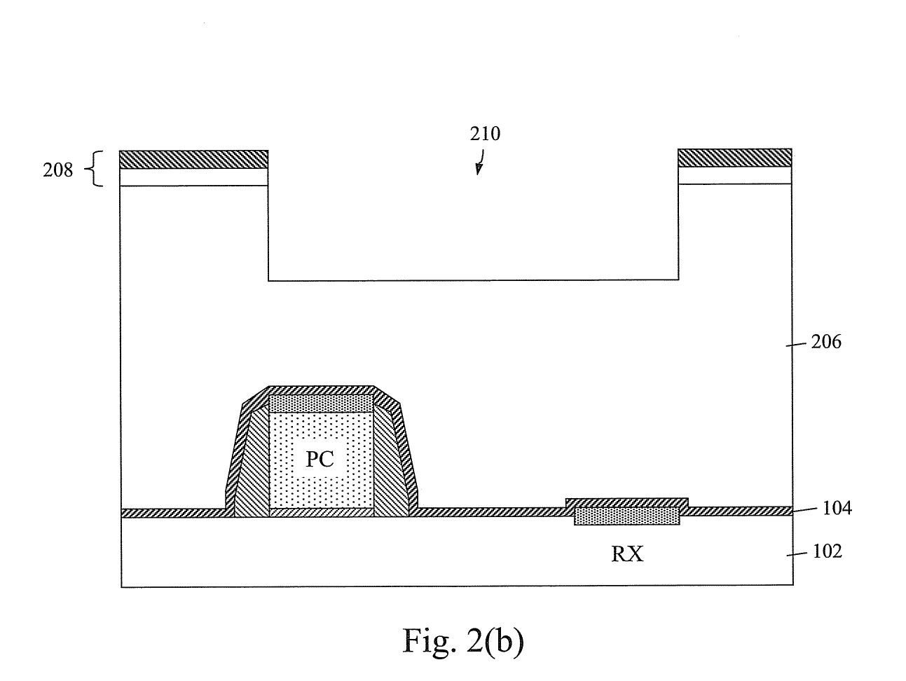

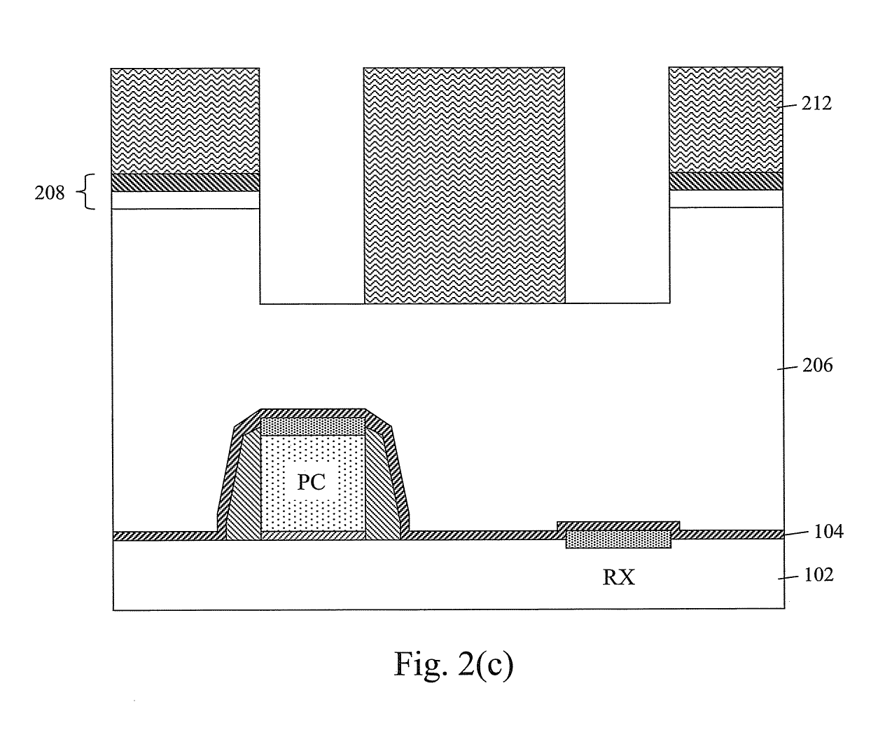

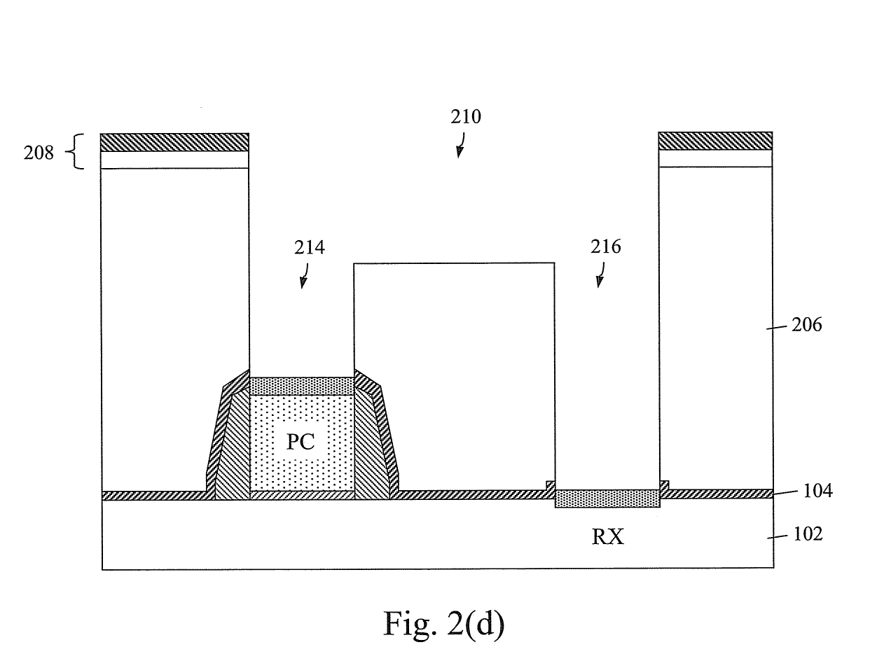

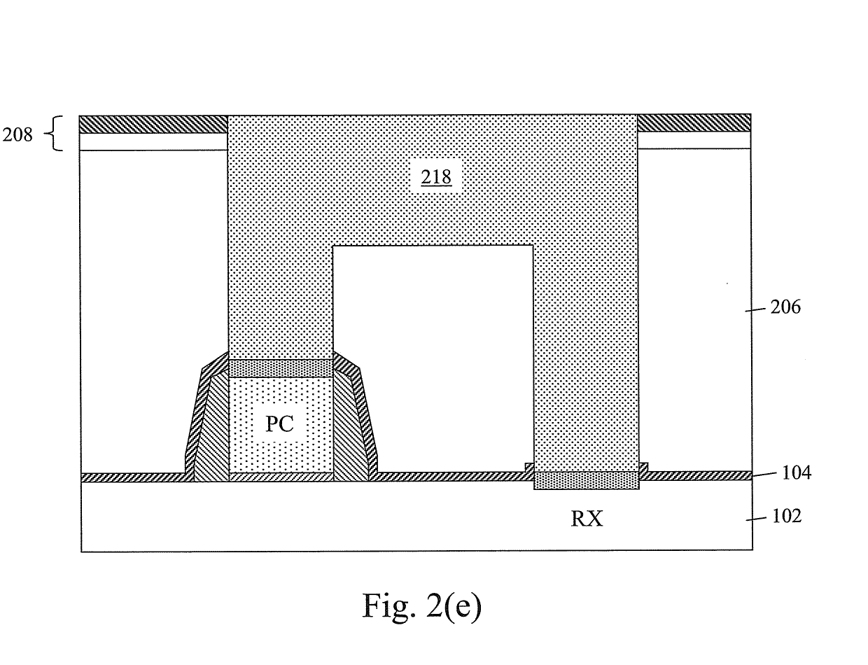

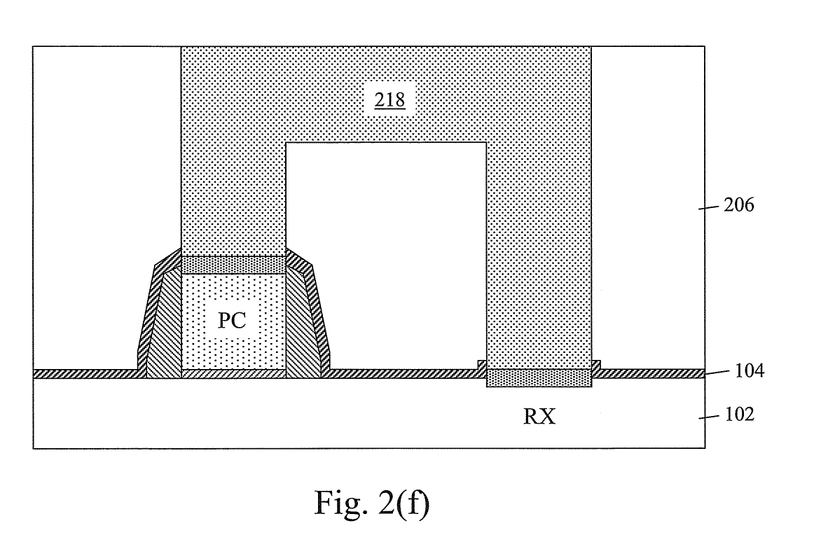

In contrast, FIGS. 2(a) through 2(f) are a series of cross sectional views illustrating a dual damascene process of forming CA/RX plugs with first metal level wiring for semiconductor devices, in accordance with an embodiment of the invention. For purposes of consistency, like structures are denoted with the same reference numerals in the figures. As shown in FIG. 2(a), the transistor structures formed in FEOL regions of the semiconductor device may be protected by a cap layer 104 (e.g., a nitride layer). Then, an ILD layer 206, such as an oxide layer, is formed over the capped transistor structures. Here, the total thickness of the oxide layer 206 represents the height of the CA and RX vias, as well as the M1 trench structures. However, unlike the process sequence of conventional tungsten plug formation, there is no extra thickness budgeted for the via portion ILD layer 206 on account of RIE. That is, the initial height of ILD layer 206 substantially corresponds to the intended final height of the vias plus the M1 trench wiring.

After formation of the ILD layer 206 in FIG. 2(a), an oxide containing hardmask 208 is then formed, followed by a photoresist layer 209. In the embodiment depicted, the disclosed dual damascene technique is a “line first” technique, in that the M1 trench pattern is defined in the photoresist layer 209 prior to defining the CA and RX via patterns. In FIG. 2(b), the pattern for the M1 trench 210 is transferred in the ILD layer 206, such as by RIE.

Then, as shown in FIG. 2(c), another patterning sequence is used to define the CA and RX vias. This may be done with, for example, another single layer of photoresist 212 as shown or, alternatively, with a tri-resist layer as described previously. Once defined, the via patterns for the CA and RX vias 214, 216, respectively are etched into the ILD layer 206 as shown in FIG. 2(d). In FIG. 2(e), a dual damascene metal formation process is used to fill both the CA and RX vias, as well as the M1 trench. Depending on the metal fill material to be used, the metal fill may be preceded by one or more liner layers (not shown) to act as a diffusion barrier. Finally, in FIG. 2(f), the metal fill (any liner layers) is planarized down to the top level of the ILD layer 206. From this point, standard BEOL processing techniques may be used to complete the device.

In one embodiment, the metal formation may be a copper deposition process, again including any appropriate liner and seed layer formations. In the case of copper, the liner may comprise a tantalum nitride/tantalum (TaN/Ta) layer. Alternatively, it is also contemplated that tungsten could be used for both MEOL plug formation and BEOL M1 metal formation, in which case the liner may comprise a titanium nitride/titanium (TiN/Ti) layer. Atomic layer deposition (ALD) of ruthenium (Ru) to reduce liner thickness is also contemplated. In still a further embodiment, it is also contemplated that a two-step metal formation process could also be used where, for example, tungsten is deposited until the vias are at least partially filled, followed by copper deposition of any remaining portions of the vias, the M1 trench, and overfill of the M1 trench. In any case, the above described line first dual damascene scheme specifically implemented at the M1 to transistor device level of a semiconductor device serves to reduce the lithography/RIE budget.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method of forming a semiconductor device, the method comprising:
forming a first interlevel dielectric (ILD) layer over one or more transistor structures formed on a substrate, the one or more transistor structures including an active area, source/drain contact and a gate conductor formed over the substrate;
forming a first metal (M1) level trench in an upper portion of the first ILD layer, followed by forming vias in a lower portion of the first ILD layer, down to the source/drain contact and down to the gate conductor; and
filling both the trench and vias with a conductive material, thereby resulting in a dual damascene metal process at and below the M1 level of the semiconductor device.

2. The method of claim 1, wherein the conductive material comprises copper.

3. The method of claim 2, further comprising forming a tantalum nitride/tantalum (TaN/Ta) layer prior to filling both the trench and vias.

4. The method of claim 1, wherein the conductive material comprises tungsten.

5. The method of claim 4, further comprising forming a titanium nitride/titanium (TiN/Ti) layer prior to filling both the trench and vias.

6. The method of claim 1, wherein the conductive material comprises tungsten filling at least a portion of the vias and copper filling any remaining portion of the vias and the trench.

7. The method of claim 1, wherein the first ILD layer is initially formed at a thickness so as to correspond to a combined height of the vias and the trench without an overbudget thickness for via height loss due to device planarization.

8. A method of forming a semiconductor device, the method comprising:
forming a first interlevel dielectric (ILD) oxide layer over a cap layer that protects one or more transistor structures formed on a substrate, the one or more transistor structures including an active area, source/drain contact and a gate conductor formed over the substrate;
forming a first metal (M1) level trench in an upper portion of the first ILD layer by photoresist pattering and reactive ion etching (RIE), followed by forming vias in a lower portion of the first ILD layer, down to the source/drain contact and down to the gate conductor by photoresist pattering and reactive ion etching (RIE); and
filling both the trench and vias with a conductive material, thereby resulting in a dual damascene metal process at and below the M1 level of the semiconductor device.

9. The method of claim 8, wherein the conductive material comprises copper.

10. The method of claim 9, further comprising forming a tantalum nitride/tantalum (TaN/Ta) layer prior to filling both the trench and vias.

11. The method of claim 8, wherein the conductive material comprises tungsten.

12. The method of claim 11, further comprising forming a titanium nitride/titanium (TiN/Ti) layer prior to filling both the trench and vias.

13. The method of claim 8, wherein the conductive material comprises tungsten filling at least a portion of the vias and copper filling any remaining portion of the vias and the trench.

14. The method of claim 8, wherein the first ILD layer is initially formed at a thickness so as to correspond to a combined height of the vias and the trench without an overbudget thickness for via height loss due to device planarization.

15. A semiconductor device, comprising:
a substrate;
one or more transistor structures formed on the substrate, including an active area, source/drain contact and a gate conductor formed over the substrate;
a first interlevel dielectric (ILD) layer formed over the one or more transistor structures, the one or more transistor; and
a first metal (M1) level trench formed in an upper portion of the first ILD layer, and vias formed in a lower portion of the first ILD layer, down to the source/drain contact and down to the gate conductor, wherein both the trench and vias are filled with copper.
